(19) United States
(12) Patent Application Publication
(10) Pub. No.: US 2026/0107564 A1
(43) Pub. Date: Apr. 16, 2026

(54) SEMICONDUCTOR DEVICE AND METHODS OF FABRICATION THEREOF

(71) Applicant: TAIWAN SEMICONDUCTOR MANUFACTURING COMPANY, LTD., Hsinchu (TW)

(72) Inventors: Guan-Xuan CHEN, Taoyuan (TW); Meng-Chieh WEN, Kaohsiung (TW); Meng-Ku CHEN, Taipei (TW); Tsai-Jung HO, Changhua (TW)

(21) Appl. No.: 19/064,850

(22) Filed: Feb. 27, 2025

Related U.S. Application Data
(60) Provisional application No. 63/706,646, filed on Oct. 12, 2024.

(51) Int. Cl. H10D 84/83; H10D 30/00; H10D 30/01; H10D 30/43; H10D 62/10; H10D 62/13; H10D 64/01; H10D 84/01

(52) U.S. Cl. CPC H10D 84/832; H10D 30/014; H10D 30/019; H10D 30/43; H10D 30/502; H10D 62/102; H10D 62/116; H10D 62/121; H10D 62/151; H10D 64/015; H10D 84/0151

(57) ABSTRACT

Embodiments of the present disclosure provide a semiconductor device including an air spacer between a source/drain contact and a gate structure and the method of forming the same. The formation of the air spacer includes forming an etch stop layer on an exposed source/drain surface, forming a sacrificial layer on the etch stop layer, depositing an isolation layer on the silicon layer, performing an anisotropic etching on the sacrificial layer while the etch stop layer protects the source/drain region to form the air spacer, and sealing the air spacer by implanting an interlayer dielectric layer above the gate structure.

### CROSS-REFERENCE TO RELATED APPLICATIONS

This application claims priority to the U.S. Provisional Patent Application Ser. No. 63/706,646 filed Oct. 12, 2024, which is incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing of a semiconductor device according to embodiments of the present disclosure.

FIGS. 2-6, 7A, 7B, 7C, 8A-8B, 9A-9B, 10A-10B, 11A-11B, 12A-12B, 13A-13B, 14A, 14B, 14C, and 14D schematically illustrate various stages of manufacturing a semiconductor device according to embodiments of the present disclosure.

FIGS. 15A-15B, 16A-16B, 17A-17B, and 18A, 18B, and 18C schematically illustrate various stages of manufacturing a semiconductor device according to embodiments of the present disclosure.

FIGS. 19A-19B, 20A-20B, 21A, 21B, 21C, 21D, and 21E schematically illustrate various stages of manufacturing a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of The semiconductor device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. Source/drain region(s) may refer to a source or a drain, individually or collectively dependent upon the context. In the present disclosure, a source/drain refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of the present disclosure provide a semiconductor device including an air spacer between a source/drain contact and a gate structure and the method of forming the same. The formation of the air spacer includes forming an etch stop layer on an exposed source/drain surface, forming a sacrificial layer on the etch stop layer, depositing an isolation layer on the silicon layer, performing an anisotropic etching on the sacrificial layer while the etch stop layer protects the source/drain region to form the air spacer, and sealing the air spacer by implanting an interlayer dielectric layer above the gate structure. In some embodiments, the etch stop layer is formed by treating the exposed surface of the source/drain regions. In some embodiments, the treatment is performed using an oxygen or nitrogen radical. In other embodiments, the etch stop layer is formed by depositing a dielectric material on the exposed source/drain surfaces. In some embodiments, the etch stop layer may be deposited on a gate sidewall spacer layer and the sacrificial layer is deposited on the etch stop layer.

Although GAA is used as an example, embodiments of the present disclosure may also be formed for other types of transistors, such as planar transistors, FinFET transistors, or the like. Also, the air spacers, in addition to be formed around source/drain contacts, may also be used to surround other types of conductive features such as conductive lines, conductive vias, etc. in order to reduce parasitic capacitance.

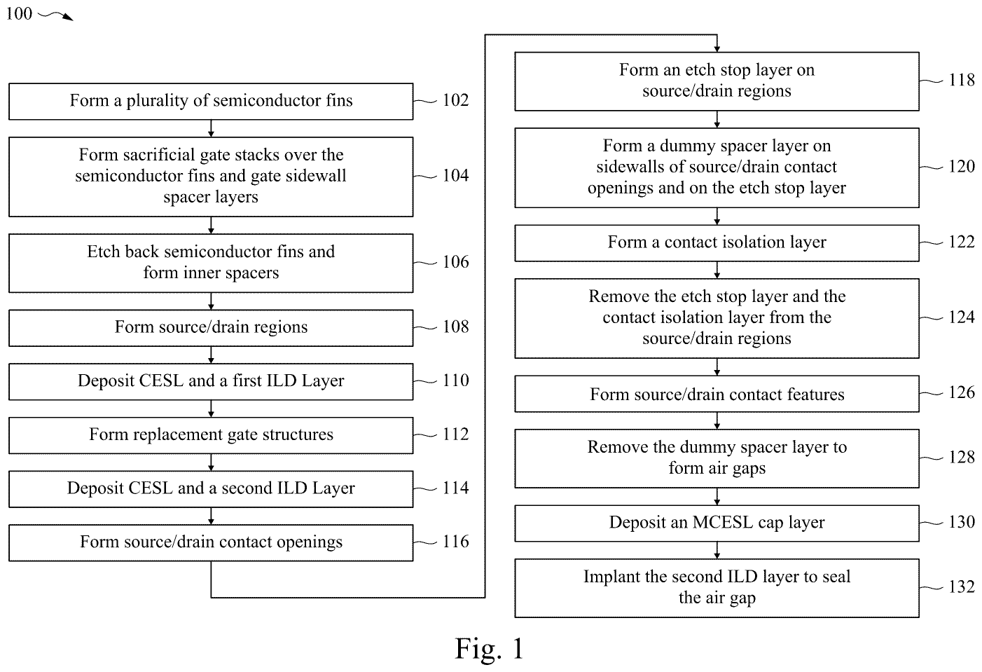

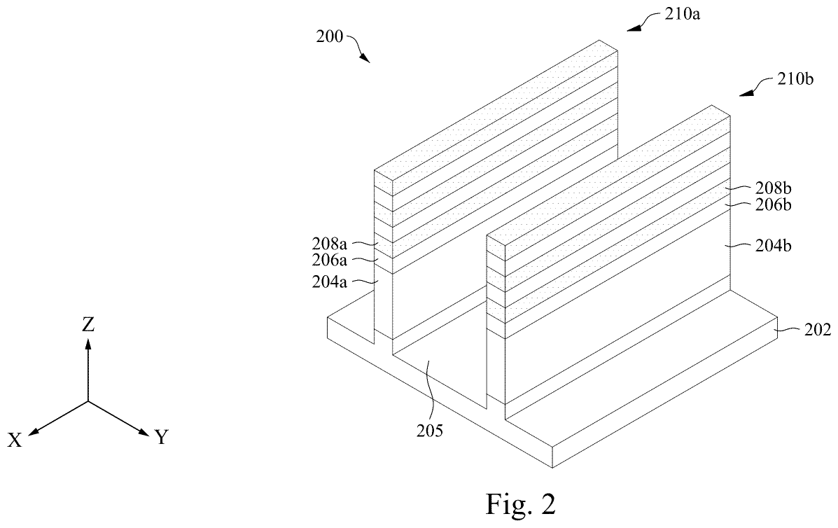

FIG. 1 is a flow chart of a method 100 for manufacturing of a semiconductor device 200 according to embodiments of the present disclosure. FIGS. 2-13 schematically illustrate various stages of manufacturing an exemplary semiconductor device 200 according to embodiments of the present disclosure. Particularly, the semiconductor device 200 may be manufactured according to the method 100 of FIG. 1.

At operation 102 of the method 100, a plurality fin structures are formed on a substrate where a semiconductor device is to be formed, as shown in FIG. 2, which is a schematic perspective view of the semiconductor device 200. A substrate 202 is provided to form the semiconductor device 200 thereon. The substrate 202 may include a single crystalline semiconductor material such as, but not limited to Si, Ge, SiGe, GaAs, InSb, GaP, GaSb, InAlAs, InGaAs, GaSbP, GaAsSb, and InP. The substrate 202 may include various doping configurations depending on circuit design. In FIG. 2, the substrate 202 includes a p-doped region or p-well 204a and an n-doped region or n-well 204b. One or more n-type devices, such as nFETs, are to be formed over and/or within p-well 204a. One or more p-type devices, such as pFETs, are to be formed over and/or within n-well 204b. FIG. 2 shows that the p-well 204a is in a doped local region of a doped substrate, which is not limiting. In other embodiments, the p-well 204a and the n-well 204b may be separated by one or more insulation bodies, e.g., STI.

A semiconductor stack including alternating first semiconductor layers 206a and second semiconductor layers 208a is formed over the p-well 204a to facilitate formation of nanosheet channels in a multi-gate n-type device, such as nanosheet channel nFETs. The first semiconductor layers 206a and second semiconductor layers 208a have different compositions. In some embodiments, the two semiconductor layers 206a and 208a provide for different oxidation rates and/or different etch selectivity. In later fabrication stages, portions of the second semiconductor layers 208a form nanosheet channels in a multi-gate device. Three first semiconductor layers 206a and three second semiconductor layers 208a are alternately arranged as illustrated in FIG. 2 as an example. More or less semiconductor layers 206a and 208a may be included depending on the desired number of channels in the semiconductor device to be formed. In some embodiments, the number of semiconductor layers 206a and 208a is between 1 and 10.

In some embodiments, the first semiconductor layer 206a may include silicon germanium (SiGe). The first semiconductor layer 206a may be a SiGe layer including more than 25% Ge in molar ratio. For example, the first semiconductor layer 206a may be a SiGe layer including Ge in a molar ration in a range between 25% and 50%. The second semiconductor layer 208a may include silicon. In some embodiments, the second semiconductor layer 208a may be un-doped Si layer. Alternatively the second semiconductor layer 208a may be a Ge layer. The second semiconductor layer 208a may include n-type dopants, such as phosphorus (P), arsenic (As), etc.

Similarly, a semiconductor stack including alternating third semiconductor layers 206b and fourth semiconductor layers 208b is formed over the n-well 204b to facilitate formation of nanosheet channels in a multi-gate p-type device, such as nanosheet channel PMOS.

In some embodiments, the third semiconductor layer 206b may include silicon germanium (SiGe). The third semiconductor layer 206b may be a SiGe layer including more than 25% Ge in molar ratio. For example, the third semiconductor layer 206b may be a SiGe layer including Ge in a molar ration in a range between 25% and 50%. The fourth semiconductor layer 208b may include silicon, Ge, a compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof. In some embodiments, the fourth semiconductor layer 208b may be a Ge layer. The fourth semiconductor layer 208b may include p-type dopants, boron etc. The material for the interposer, 206a and 206b, may be replaced by silicon oxide or silicon nitride in the following processes in some embodiments.

The semiconductor layers 206a, 206b, 208a, 208b may be formed by a molecular beam epitaxy (MBE) process, a metalorganic chemical vapor deposition (MOCVD) process, and/or other suitable epitaxial growth processes. The semiconductor stacks over the n-well 204b and the p-well 204a may be formed separately using patterning technology.

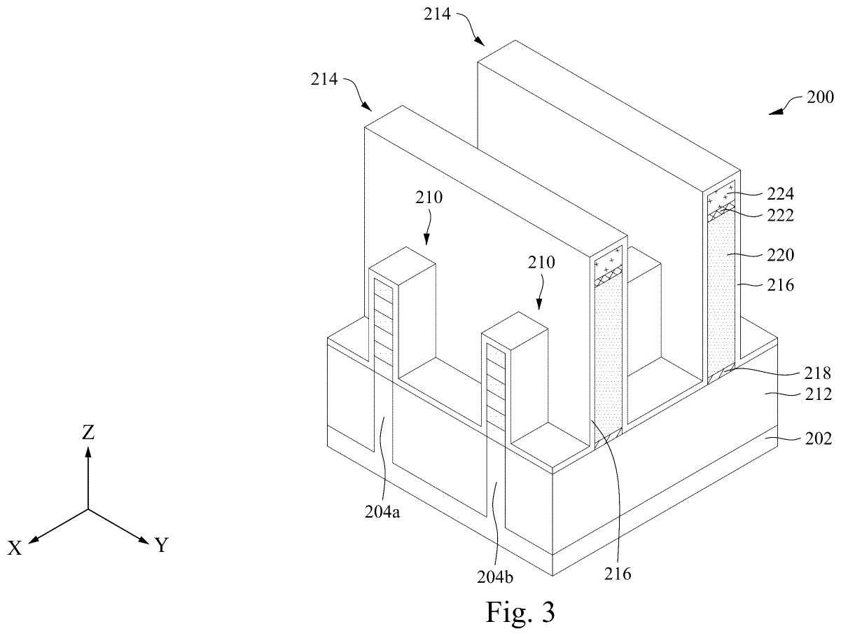

Fin structures 210a, 210b (collectively 210) are then formed from etching the semiconductor stacks and a portion of the n-well 204b, the p-well 204a underneath respectively, as shown in FIG. 3. The fin structures 210a, 210b are substantially parallel and are separated by trenches 205. Even though, fin structures 210a, 210b for nanosheet FET devices are shown in the semiconductor device 200, embodiments of the present disclosure are also applicable to planar FETs, Fin-FETs, Horizontal Gate All Around (HGAA) FETs, Vertical Gate All Around (VGAA) FETs, and other suitable devices.

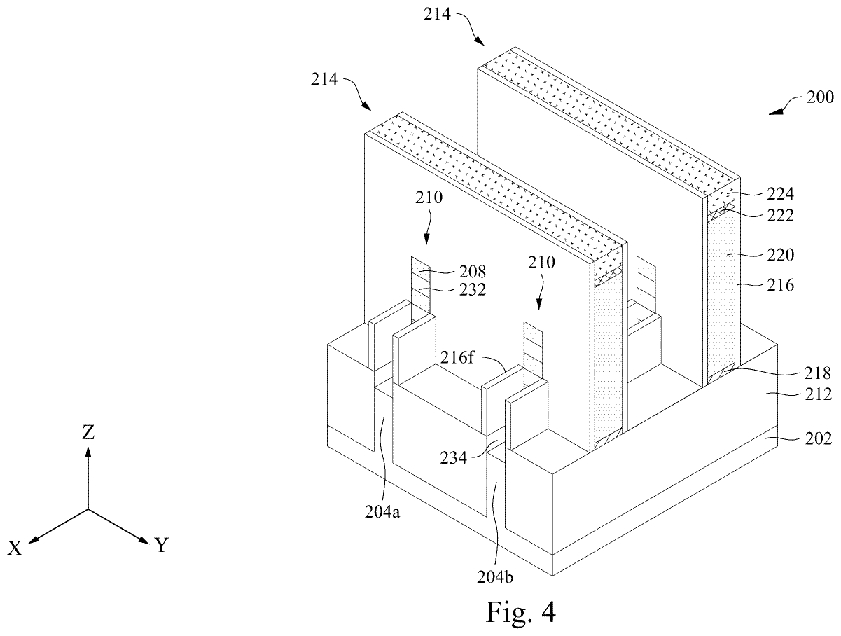

At operation 104, sacrificial gate structures 214 are formed over the isolation layer 212 over the fin structures 210a, 210b, and gate sidewall spacer layer 216 layer is formed, as shown in FIG. 3, which is a schematic view of the semiconductor device 200. An isolation layer 212 is filled in trenches 215 between the fin structures 210a, 210b and then etched back to below the semiconductor stacks of the fin structures 210a, 210b. The isolation layer 212 may be formed by a high-density plasma chemical vapor deposition (HDP-CVD), a flowable CVD (FCVD), or other suitable deposition process. In some embodiments, the isolation layer 212 may include silicon oxide, silicon nitride, silicon oxynitride, fluorine-doped silicate glass (FSG), a low-k dielectric, combinations thereof. In some embodiments, the isolation layer 212 is formed to cover the fin structures 210a, 210b by a suitable deposition process to fill the trenches 205 between the fin structures 210a, 210b, and then recess etched using a suitable anisotropic etching process to expose the active portions of the fin structures 210a, 210b. As shown in FIG. 4, after operation 104, the isolation layer 212 fills bottom portions of the trenches 205 between fin structures 210. Particularly, the stacks of semiconductor layers 206a, 206b, 208a, 208b extend above a top surface 212t of the isolation layer 212.

The sacrificial gate structures 214 are formed over the isolation layer 212 and around the exposed portions of the fin structures 210a, 210b. The sacrificial gate structures 214 are formed over portions of the fin structures 210a, 210b which are to be channel regions. Trenches 215 are formed between neighboring sacrificial gate structures 214. The sacrificial gate structures 214 are substantially perpendicular to the fin structures 210.

The sacrificial gate dielectric layer 218 may be formed conformally over the fin structures 210a, 210b, and the isolation layer 212. In some embodiments, the sacrificial gate dielectric layer 218 may be deposited by a CVD process, a sub-atmospheric CVD (SACVD) process, a FCVD process, an ALD process, a PVD process, or other suitable process. The sacrificial gate dielectric layer 218 may include one or more layers of dielectric material, such as SiO₂, SiN, a high-k dielectric material, and/or other suitable dielectric material.

The sacrificial gate electrode layer 220 may be blanket deposited on the sacrificial gate dielectric layer 218. The sacrificial gate electrode layer 220 includes silicon such as polycrystalline silicon or amorphous silicon. The thickness of the sacrificial gate electrode layer is in a range between about 42 nm and about 200 nm. In some embodiments, the sacrificial gate electrode layer 220 is subjected to a planarization operation. The sacrificial gate electrode layer 220 may be deposited using CVD, including LPCVD and PECVD, PVD, ALD, or other suitable process.

Subsequently, the pad layer 222 and the mask layer 224 are formed over the sacrificial gate electrode layer 220. The pad layer 222 may include silicon nitride. The mask layer 224 may include silicon oxide. Next, a processing sequence including patterning and etching is performed on the mask layer 224, the pad layer 222, the sacrificial gate electrode layer 220 and the sacrificial gate dielectric layer 218 to form the sacrificial gate structures 214. Portions of the sacrificial gate electrode layer 220 and the sacrificial gate dielectric layer 218 are sequentially removed using patterns formed in the mask layer 224 to form the sacrificial gate structures 214.

After the sacrificial gate structures 214 are formed, the gate sidewall spacer layer 216 may be deposited over the semiconductor device 200 by a blanket deposition of one or more insulating material. Even though only one layer is shown in FIG. 4, the gate sidewall spacer layer 216 may include two or more layers of dielectric materials. In some embodiments, the gate sidewall spacer layer 216 may include one or more insulation material. The gate sidewall spacer layer 216 may include a silicon nitride-based material, such as SiN, SiON, SiOCN or SiCN and combinations thereof.

In operation 106, the fin structures 210 not covered by the sacrificial gate structures 214 are etched to expose well portions of each fin structures 210 to form source/drain recesses 234, as shown in FIG. 4. In some embodiments, suitable dry etching and/or wet etching may be used to etch back the semiconductor layers 206, 208, together or separately. A portion of the fin sidewall spacers 216f may remain after the fin structures 210 are recessed. A height of the remaining fin sidewall spacers 216f may be used to control the shape of the subsequently formed epitaxial source/drain regions.

After recess etch of the fin structures 210, inner spacers 232 are formed through the source/drain recesses 234. To form the inner spacers 232, the semiconductor layers 206 under the gate sidewall spacers 216g are selectively etched from the semiconductor layers 208 along the horizontal direction, or x-direction, to form spacer cavities. In some embodiments, the semiconductor layers 206 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. After forming the spacer cavities, the inner spacers 232 are formed in the spacer cavities by conformally deposit and then partially remove an insulating layer. The insulating layer can be formed by ALD or any other suitable method. The subsequent etch process removes most of the insulating layer except inside the cavities, resulting in the inner spacers 232.

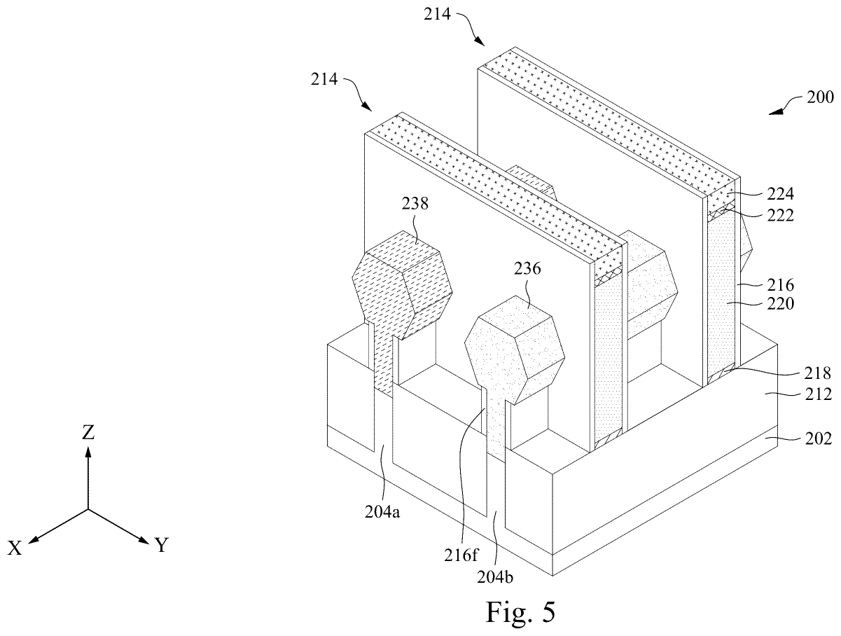

At operation 108, epitaxial source/drain regions 236, 238 are formed, as shown in FIG. 5, which is a schematic perspective view of the semiconductor device 200. In some embodiments, the epitaxial source/drain regions 236. 238 may be for different types of devices and may be formed separately using patterning processes.

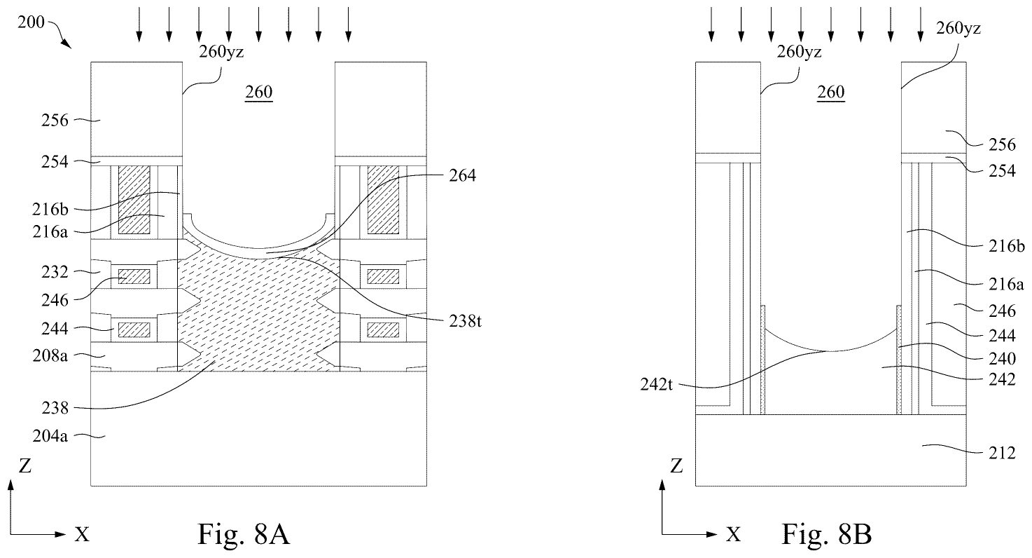

In some embodiments, the epitaxial source/drain regions 236 for N-type devices are formed from exposed surfaces of the fin structure 210b. The epitaxial source/drain regions 236 for n-type devices may include one or more layers of Si, SiP, SiC and SiCP. The epitaxial source/drain regions 236 also include N-type dopants, such as phosphorus (P), arsenic (As), etc. In some embodiments, the epitaxial source/drain regions 236 may be a Si layer includes phosphorus (P) dopants. The epitaxial source/drain regions 236 shown in FIG. 8 has an oval shape. However, the epitaxial source/drain regions 236 may be other shapes according to the design. The epitaxial source/drain regions 236 may be formed by any suitable method, such as by CVD, CVD epitaxy, molecular beam epitaxy (MBE), or any suitable deposition technique.

The epitaxial source/drain regions 238 may be for P-type devices. The epitaxial source/drain regions 238 may be formed by any suitable method, such as by CVD, CVD epitaxy, molecular beam epitaxy (MBE), or any suitable deposition technique. In some embodiments, the epitaxial source/drain regions 238. The epitaxial source/drain regions 238 for the p-type devices may include one or more layers of Si, SiGe, Ge with p-type dopants, such as boron (B), for a p-type device, such as pFET. In some embodiments, the epitaxial source/drain regions 238 may be SiGe material including boron as dopant. The sequence of the formation of epitaxial source/drain for NMOS and PMOS are exchangeable, subject to the requirement for the process requirement. The shape of epitaxial source/drain may be different for NMOS and PMOS, subject to the design of film scheme.

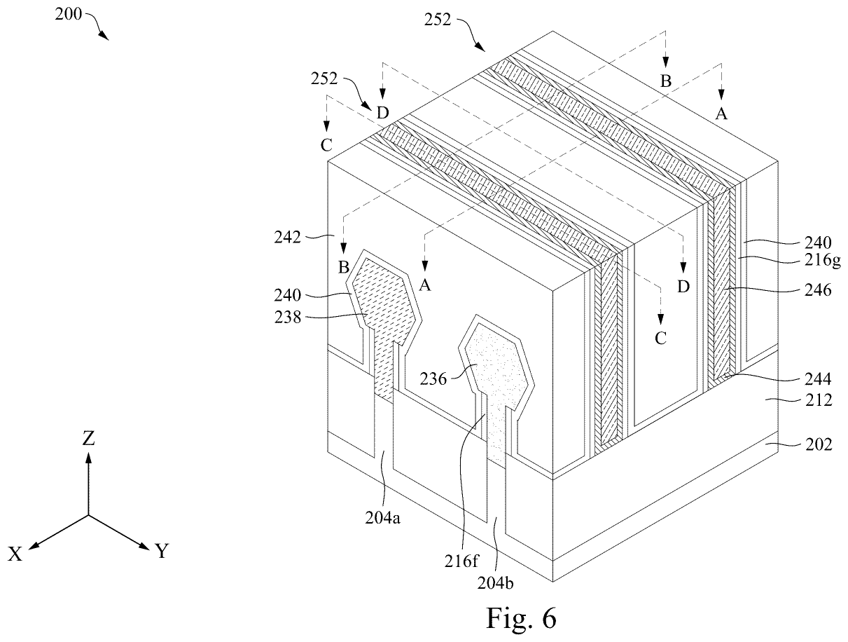

At operation 110, a contact etch stop layer (CESL) 240 and an interlayer dielectric (ILD) layer 242 are conformally formed over the semiconductor device 200, as shown in FIG. 6, which is a schematic perspective view of the semiconductor device 200.

The CESL 240 is formed over exposed surfaces of the semiconductor device 200. The CESL 240 is formed on the epitaxial source/drain regions 236, 238 the gate sidewall spacers 216g, the fin sidewall spacers 216f, and the isolation layer 212. The CESL 240 may include Si₃N₄, SION, SiCN or any other suitable material, and may be formed by CVD, PVD, or ALD.

The ILD layer 242 is formed over the contact etch stop layer 240. The materials for the ILD layer 242 include compounds comprising Si, O, C, and/or H, such as silicon oxide, SiCOH and SiOC. Organic materials, such as polymers, may be used for the ILD layer 242. In some embodiments, the ILD layer 242 may be formed by flowable CVD (FCV). The ILD layer 242 and the CESL layer 240 protect the epitaxial source/drain regions 236, 238 during the removal of the sacrificial gate structures 214. In some embodiments, after depositing the ILD layer 242, a planarization process may be performed to expose the sacrificial gate structures 214.

At operation 112, replacement gate structures 252 are formed as shown in FIG. 6. In some embodiments, the sacrificial gate dielectric layer 218 and the sacrificial gate electrode layer 220 are removed using dry etching, wet etching, or a combination. The semiconductor layers 206a, 206b are exposed and subsequently removed resulting in gate cavities surrounding nanosheets of the semiconductor layers 208a, 208b. Replacement gate structures 252 are then filled in the gate cavities. The replacement gate structures 252 may include a gate dielectric layer 244 and a gate electrode layer 246.

The gate dielectric layer 244 is formed on exposed surfaces in the gate cavities. The gate dielectric layer 244 may have different composition and dimensions for N-type devices and P-type devices and are formed separately using patterned mask layers and different deposition recipes. The gate dielectric layer 244 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 244 may be formed by CVD, ALD or any suitable method.

The gate electrode layer 246 is formed on the gate dielectric layer 244 to fill the gate cavities. The gate electrode layer 246 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the gate electrode layer 246 may be formed by CVD, ALD, electro-plating, or other suitable method.

After the formation of the gate electrode layer 246, a planarization process, such as a CMP process, is performed to remove excess deposition of the gate electrode material and expose the ILD layer 242.

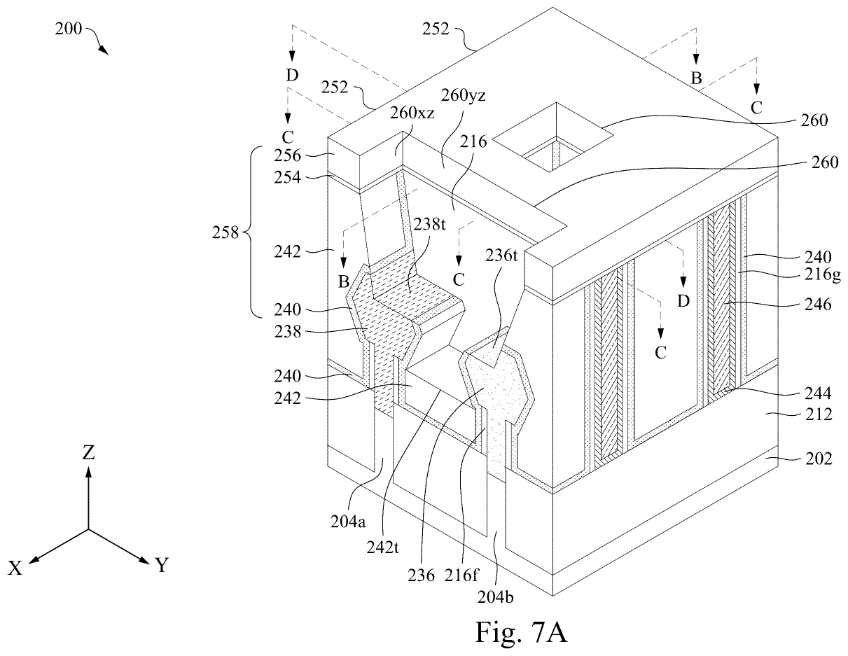

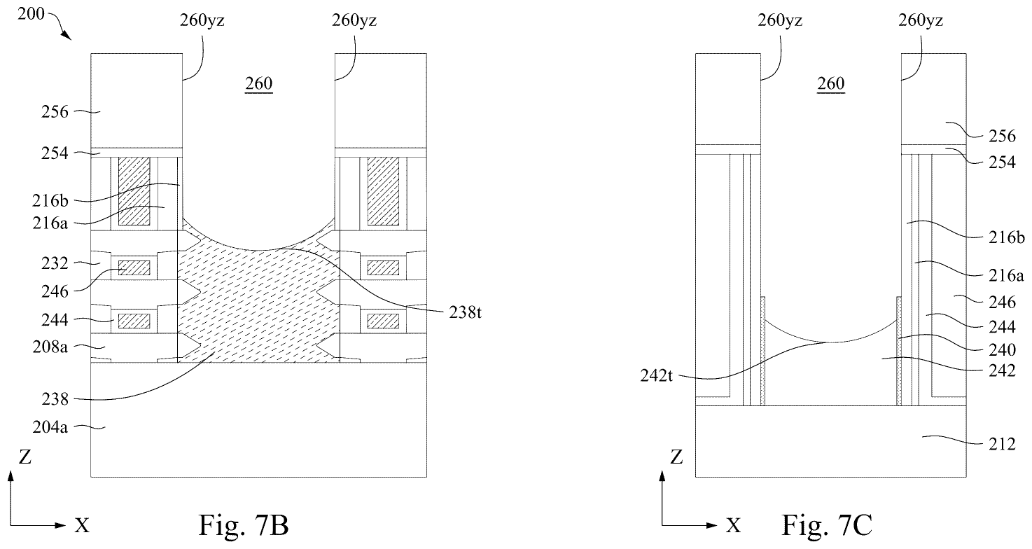

At operation 114, an etch stop layer (ESL) 254 and an interlayer dielectric (ILD) layer 256 are conformally formed over the semiconductor device 200, as shown in FIG. 7A, which is a schematic perspective view of the semiconductor device 200. The ESL 254 may include silicon and nitrogen and/or carbon (for example, SiN, SiCN, SiCON, SiON, SiC, and/or SiCO) (and can thus be referred to as silicon nitride layers). The ESL 254 may be formed by CVD, PVD, or ALD.

The ILD 256 may include a dielectric material, for example, silicon oxide, silicon nitride, silicon oxynitride, tetraethyl orthosilicate (TEOS) oxide, PSG, BPSG, low-k dielectric material, other suitable dielectric material, or combinations thereof. Low-k dielectric material generally refers to dielectric materials having a low dielectric constant relative to the dielectric constant of silicon dioxide (k=3.9). For example, low-k dielectric material has a dielectric constant less than about 3.9. In some examples, low-k dielectric material has a dielectric constant less than about 2.5, which can be referred to as extreme low-k dielectric material. Exemplary low-k dielectric materials include fluorosilicate glass (FSG), carbon doped silicon oxide, Black Diamond® (Applied Materials of Santa Clara, California), Xerogel, Aerogel, amorphous fluorinated carbon, Parylene, BCB, SILK (Dow Chemical, Midland, Michigan), polyimide, other low-k dielectric material, or combinations thereof.

In some embodiments, the ILD 256 include a low-k dielectric material and is generally referred to as low-k dielectric layers. The ESL 254 includes a material different than ILD layers 242, 256. The ILD layers 242, 256 and the CESLs 240, 254 may be a multilayer structure having multiple dielectric materials. In some embodiments, the ILD layers 242, 256 and the ESL layers 240, 254 may be collectively referred to as multilayer interconnect (MLI) feature 250.

In operation 116, one or more source/drain contact openings 260 are formed through the MLI feature 250 to expose the source/drain regions 236, 248, as shown in FIGS. 7A, 7B, and 7C. FIG. 7B is a schematic cross-sectional view of the semiconductor device 200 along the line B-B in FIG. 7A. FIG. 7C is a schematic cross-sectional view of the semiconductor device 200 along the line C-C in FIG. 7A. Particularly, FIG. 7B schematically demonstrates the source/drain contact opening 260 along the fin structure 210a, and FIG. 7C schematically demonstrates the source/drain opening between the fin structures 210a, 210b, or over the isolation layer 212.

To form the source/drain contact opening 260, a mask (not shown) may be formed over the ILD layer 256. One or more etch processes may be performed to remove the MLI feature 250 over the source/drain region 236, 238 to expose the source/drain regions 236, 238. In some embodiments, portions of the source/drain regions 236, 238 are also removed to expose the semiconductor materials in the source/drain regions 236, 238 to generate a contact surface. In FIGS. 7A and 7B, a top surface 238t of the source/drain region 238 and a top surface 236t of the source/drain region 236 are exposed to and define a bottom surface of the source/drain contact opening 260. In the example of FIGS. 7A-7C, the source/drain contact opening 260 expands the neighboring source/drain regions 236, 238. A top surface 242t of the ILD layer 242 also defines the bottom surface of the source/drain contact opening 260.

Depending on the circuit design, the source/drain contact openings 260 may be formed over a single source/drain region or two or more source/drain regions. In some embodiments, the source/drain contact opening 260 may be deeper over the isolation layer 212 between the source/drain regions 236, 238. Thus, the top surface 242t of the ILD layer 242 is lower than the top surfaces 238t, 236t of the source/drain regions 238, 236.

The source/drain contact opening 260 may be substantially rectangular in shape having sidewalls 260yz along the direction of y-z plane and sidewalls 260xz along the direction of x-z plane. As shown in FIG. 7A, the sidewalls 260xz may be include surfaces of the ILD layer 256, the ESL 254, the CESL 240, the ILD layer 242, and a portion of the source/drain regions 236, 238. As shown in FIGS. 7B and 7C, the sidewalls 260yz may be aligned with the gate sidewall spacer layer 216. In FIGS. 7B and 7C, the gate sidewall spacer layer 216 includes an inner layer 216a in contact with the gate structures 252 and an outer layer 216b exposed to the source/drain contact opening 260. The sidewalls 260yz may include surfaces of the ILD layer 256, the ESL 254, and the outer layer 216b of the gate sidewall spacer layer 216.

In operation 118, an etch stop layer 264 is formed over the top surface 238t, 236t, or the exposed surfaces of the source/drain regions 238, 236, as shown in FIGS. 8A and 8B. The etch stop layer 264 is configured to protect the source/drain regions 238, 236 during subsequent air spacer formation processes. The etch stop layer may be formed by various methods.

In some embodiments, the etch stop layer 264 is formed by treating exposed source/drain regions with a radial, such as treatment by oxygen or nitrogen containing plasma. The etch stop layer 264 may be oxygen or nitrogen containing material, for example an oxide or a nitride of the semiconductor material in the source/drain regions 238, 236. In some embodiments, the etch stop layer 264 may have a thickness in a range between about 1 nm and about 5 nm. A thickness less than 1 nm may not provide sufficient protection to the source/drain regions 238, 236. A thickness greater than 5 nm may reduce volume of the air spacer to be formed without providing additional benefit.

As shown in FIGS. 8A and 8B, the etch stop layer 264 may only form on the top surfaces 238t and 236t of the source/drain regions 238, 236. The dielectric layers exposed to the source/drain contact openings 260 already include oxide material or nitride material, therefore, no detectable layer.

In some embodiments, the plasma treatment includes flowing a nitrogen-containing gas or an oxygen-containing gas and a carrier gas into a process chamber, generating a nitrogen-containing or oxygen-containing plasma therefrom, and bombarding the source/drain regions 236, 238 with plasma-excited species. The nitrogen-containing gas can include N₂ (diatomic nitrogen), NH₃ (ammonia), N₂O (nitrous oxide), other suitable nitrogen-containing precursor, or combinations thereof. The oxygen-containing gas may include O₂, and the like. The carrier gas may be an inert gas, such as an argon-containing gas, a helium-containing gas, a xenon-containing gas, other suitable gas, or combinations thereof. In some embodiments, an RF power used to generate the plasma is about 80 W to about 3,000 W. In some embodiments, a duration of nitrogen plasma treatment is about 10 seconds to about 500 seconds. In some embodiments, the plasma treatment is performed at a pressure of about 1 torr to about 20 torr and/or at a temperature of about 250° C. to about 550° C.

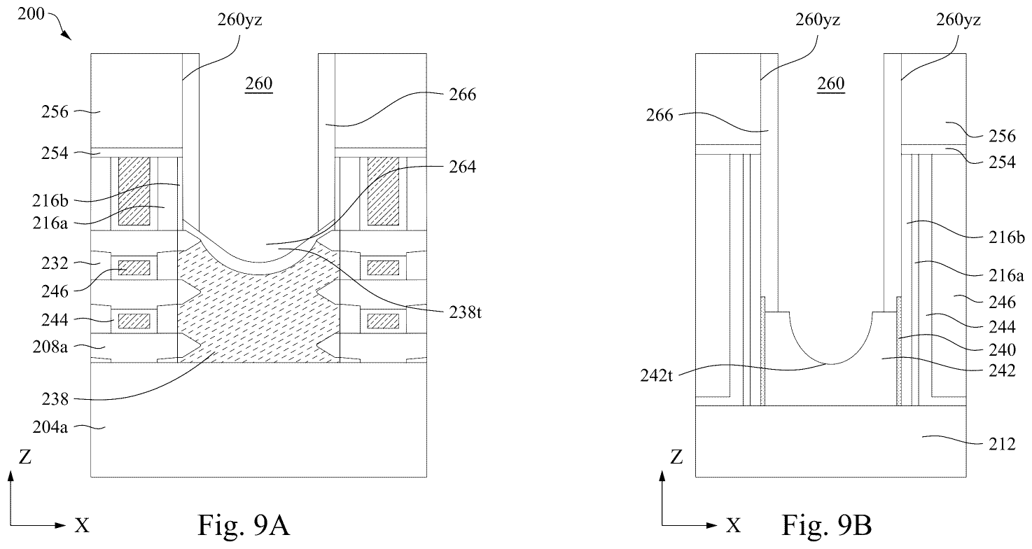

In operation 120, a dummy spacer layer 266 is formed over the sidewalls 260xz and 260yz of the source/drain contact opening 260, as shown in FIGS. 9A-9B. The dummy spacer layer 266 is subsequently removed to form an air spacer around the source/drain contact to be formed. The dummy spacer layer 266 is disposed along sidewalls formed on vertical surfaces, such as the sidewalls 260xz and 260yz of the source/drain contact opening 260. As shown in FIGS. 9A and 9B, the dummy spacer layer 266 may be formed on surfaces of the ILD layer 256, the ESL 254, the outer layer 216b of the gate sidewall spacer layer 216. The etch stop layer 264 is disposed between the source/drain regions 236/238 and the dummy spacer layer 266.

In some embodiments, the dummy spacer layer 266 has a substantially uniform thickness along the sidewalls 260xz and 260yz of the source/drain contact opening 260. However, the present disclosure contemplates embodiments where a thickness of dummy spacer layer 266 varies (for example, tapers) along the sidewalls 260xz and 260yz of the source/drain contact opening 260. In some embodiments, a thickness of dummy spacer layer 266 defined along the x-direction is about 0.5 nm to about 5 nm.

A composition of dummy spacer layer 266 is different than compositions of layers surrounding dummy spacer layer 266, such as the ILD layers 242, 256, the CESLs 240, 254, and the etch stop layer 264 to achieve etching selectivity during subsequent etching processes to form the air spacers. In some embodiments, the dummy spacer layer 266 includes a material having an etch rate to an etchant that is greater than an etch rate of materials of the ILD layers 242, 256, the CESLs 240, 254, and the etch stop layer 264 to the etchant. In some embodiments, materials of the dummy spacer layer 266 and its surrounding layers are tailored to achieve an etch selectivity (i.e., a ratio of an etch rate of dummy spacer layer 266 to an etch rate of its surrounding layers) of about 10:1 to about 1,000:1.

In some embodiments, the dummy spacer layer 266 includes silicon, germanium, oxygen, nitrogen, carbon, other suitable constituent, or combinations thereof. In some embodiments, the dummy spacer layer 266 is a polysilicon layer. In some embodiments, the dummy spacer layer 266 is a silicon layer, a germanium layer, or a silicon germanium layer. In some embodiments, the dummy spacer layer 266 includes a silicon layer, a germanium layer, or a silicon germanium layer, doped with a suitable dopant to achieve desired etching selectivity. In some embodiments, the dummy spacer layer 266 is an amorphous silicon layer. In some embodiments, the dummy spacer layer 266 is a BSG layer or a PSG layer. In some embodiments, the dummy spacer layer 266 is a low-density silicon nitride layer. In some embodiments, dummy spacer layer 266 is a low-density silicon oxide layer, for example, relative to ILD layers 242, 256.

In some embodiments, the dummy spacer layer 266 may be formed by a blanket deposition followed by an anisotropic etching to remove horizontal portions. During the anisotropic etching, the etch stop layer 264 formed on the source/drain regions 238, 236 protects the source/drain regions 238, 236.

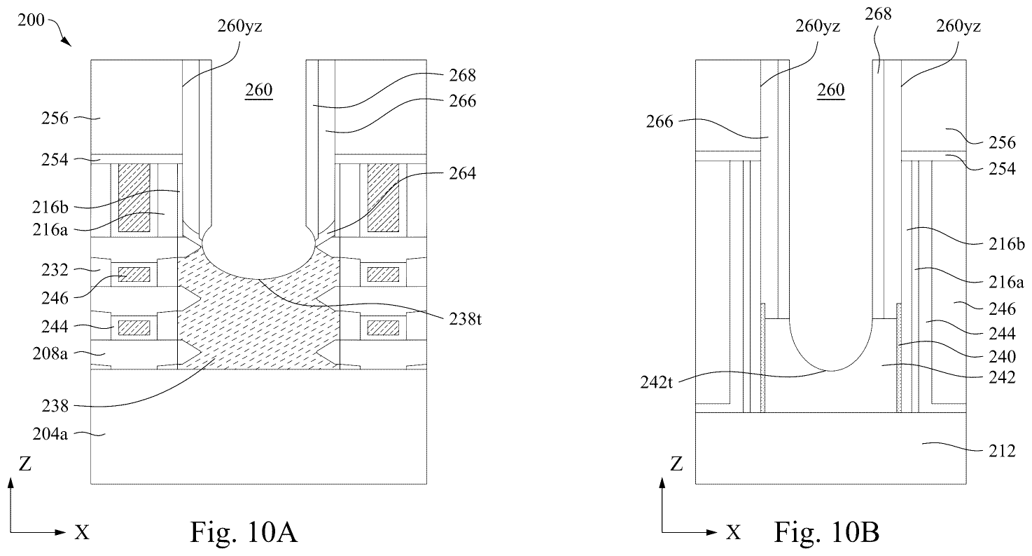

In operation 122, a contact isolation layer 268 is deposited over the dummy spacer layer 266, as shown in FIGS. 10A-10B. The contact isolation layer 268 is disposed over the dummy spacer layer 266 and configured to provide isolation to the source/drain contact to be formed. The contact isolation layer 268 has a substantially uniform thickness along sidewalls of the source/drain contact opening 260. In some embodiments, the contact isolation layer 268 has a thickness in a range between about 0.5 nm and about 5 nm. The contact isolation layer 268 is formed from a material that facilitates etching selectivity between the contact isolation layer 268 and the dummy spacer layer 266 during subsequent processing. In some embodiments, the contact isolation layer 268 is a nitrogen-comprising layer. For example, the contact isolation layer 268 includes silicon and nitrogen and optionally carbon, such as SiN, SiCN, carbon-doped SiN, high-density SiN, low-density SiN, other silicon-and-nitrogen-comprising material, or combinations thereof. In some embodiments, the contact isolation layer 268 is a high-density SiN layer. In some embodiments, the contact isolation layer 268 may be formed by a blanket deposition followed by an anisotropic etching to remove horizontal portions.

In operation 124, the etch stop layer 264 is removed from the source/drain regions 236/238, as shown in FIGS. 10A-10B. The etch stop layer 264 may be removed by an anisotropic etching process. In some embodiments, the etch stop layer 264 and the horizontal portions of the contact isolation layer 268 may be removed in the same process. After operation 124, strips of the etch stop layer 264 remain between the dummy spacer layer 266 and the source/drain regions 238, 236.

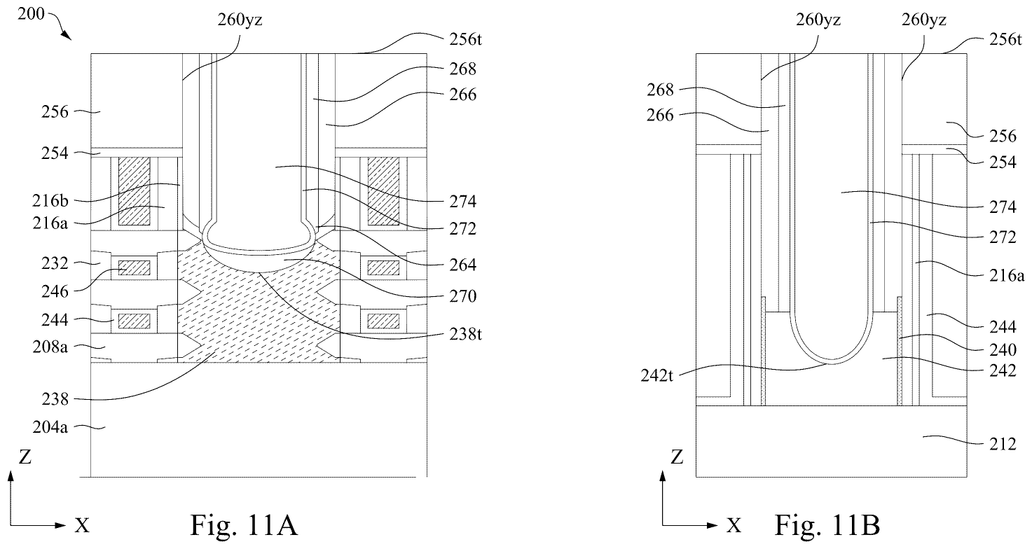

In operation 126, source/drain contact features 274 are formed in the source/drain contact opening 260, as shown in FIGS. 11A-11B. A silicide layer 270 is selectively formed over surfaces of the epitaxial source/drain regions 236, 238 exposed by the source/drain contact openings 260. The silicide layer 270 may be formed by depositing a metal source layer to cover exposed surfaces including the exposed surfaces of the epitaxial source/drain regions 236, 238 and performing a rapid thermal annealing process. In some embodiments, the metal source layer includes a metal layer selected from W, Co, Ni, Ti, Mo, and Ta, or a metal nitride layer selected from tungsten nitride, cobalt nitride, nickel nitride, titanium nitride, molybdenum nitride, and tantalum nitride. After the formation of the metal source layer, a rapid thermal anneal process is performed. During the rapid anneal process, the portion of the metal source layer over the epitaxial source/drain regions 236, 238 reacts with silicon in the epitaxial source/drain regions 236, 238 to form the silicide layer 270. Unreacted portion of the metal source layer is then removed. In some embodiments, the silicide layer includes one or more of WSi, CoSi, NiSi, TiSi, MoSi, and TaSi.

After formation of the silicide layer 270, a conductive material is deposited to fill the source/drain contact openings 260 and form the source/drain contact features 274. Optionally, a contact barrier layer 272 may be formed in the source/drain contact openings 260 prior to forming the source/drain contact features 274.

The contact barrier layer 272 may include a material that promotes adhesion between a dielectric material, for example the contact isolation layer 268, and a metal material, for example the source/drain contact feature 274. In some embodiments, the contact barrier layer 272 includes titanium, titanium alloy, tantalum, tantalum alloy, cobalt, cobalt alloy, ruthenium, ruthenium alloy, molybdenum, molybdenum alloy, other suitable constituent configured to promote and/or enhance adhesion between a metal material and a dielectric material, or combinations thereof. In some embodiments, the contact barrier layer 272 includes tantalum and nitrogen (for example, tantalum nitride) or titanium and nitrogen (for example, titanium nitride). In some embodiments, the contact barrier layer 272 includes multiple layers. For example, the contact barrier layer 272 may include a first sub-layer that includes titanium and a second sub-layer that includes titanium nitride. In another example, the contact barrier layer 272 may include a first sub-layer that includes tantalum and a second sub-layer that includes tantalum nitride.

In some embodiments, the conductive material layer for the source/drain contact features 274 may be formed by CVD, PVD, plating, ALD, or other suitable technique. In some embodiments, the conductive material for the source/drain contact features 274 includes a metal material, tungsten, ruthenium, cobalt, copper, aluminum, iridium, palladium, platinum, nickel, low resistivity metal constituent, alloys thereof, or combinations thereof. Subsequently, a CMP process is performed to remove a portion of the conductive material layer above a top surface 256t of the ILD layer 256.

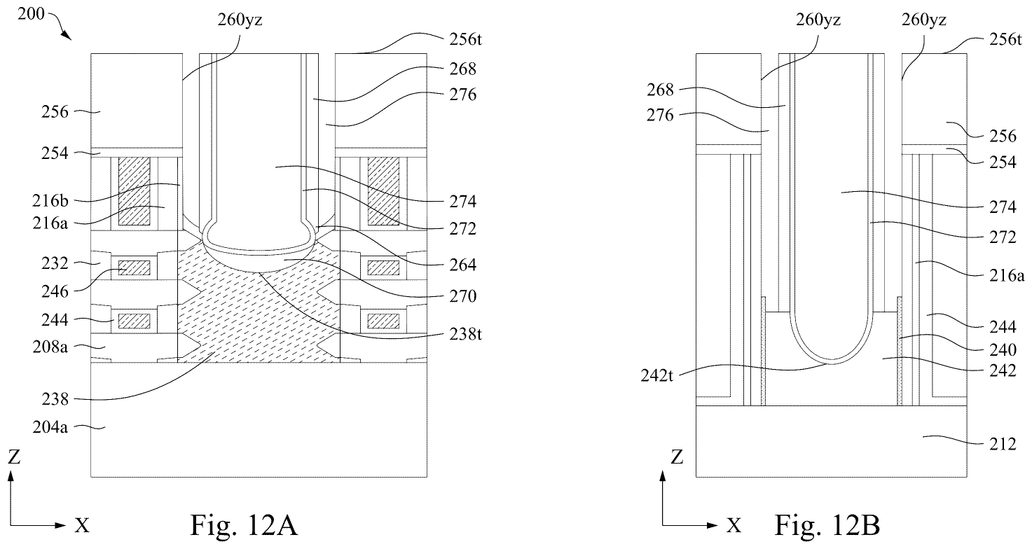

In operation 128, the dummy spacer layer 266 is removed to form an air spacer 276 around the source/drain contact features 274, as shown in FIGS. 12A-12B. Removal of portions of the dummy spacer layer 266 may be performed by any suitable method, such as an etching process. In one example, the etching process is an anisotropic dry etch process that utilizes fluorine or chlorine based etchant. The chlorine or fluorine based etchant selectively removes the portions of the dummy spacer layer 266.

In some embodiments, when the dummy spacer layer 266 includes silicon, the etch process may be performed using F radicals or H radicals by the following reactions:

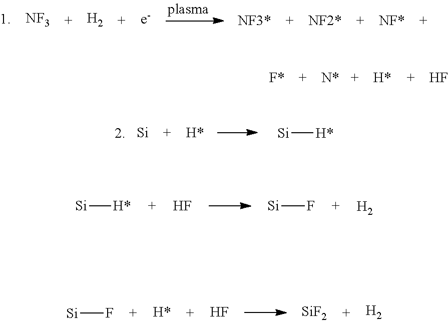

The remaining etch stop layer 264 under the dummy spacer layer 266 protects the source/drain regions 238, 236 underneath when the dummy spacer layer 266 is completely removed. As shown in FIGS. 9A and 9B, the dummy spacer layer 266 may be longer along the z-direction over the STI region (shown in FIG. 9B) than over the source/drain region 236/238 (shown in FIG. 9A), which indicates that the dummy spacer layer 266 over the source/drain regions 236/238 may be substantially removed before the dummy spacer layer 266 above the STI region may be substantially removed. The etch stop layer 264 that is positioned over the source/drain region 236/238 ensures that the dummy spacer layer 266 may be substantially removed without damaging the source/drain region 236/238.

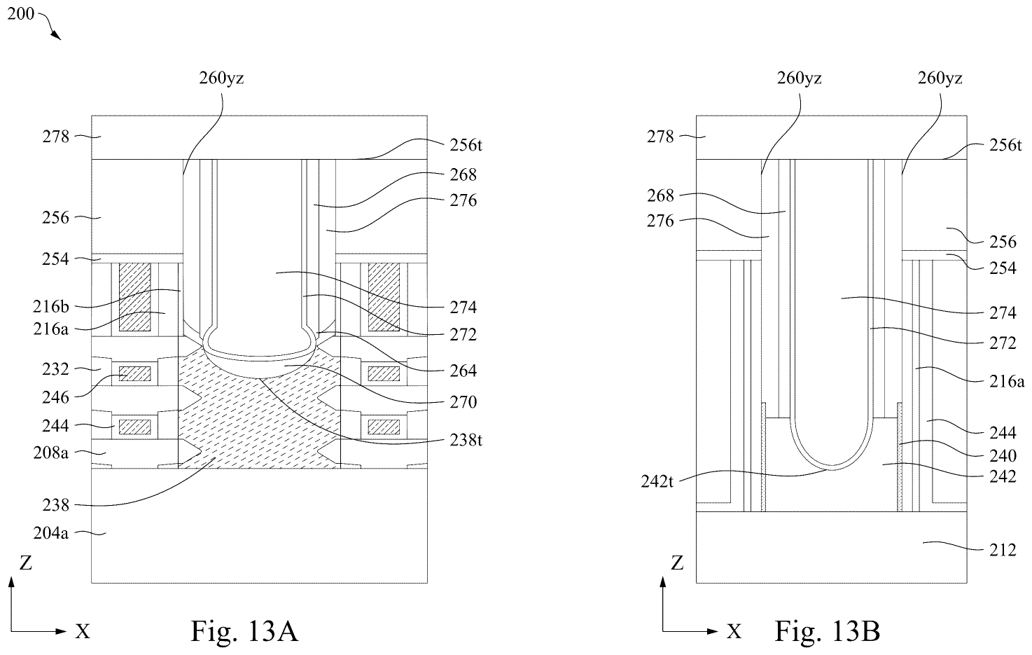

In operation 130, a cap layer 278 is deposited over the ILD layer 256, as shown in FIGS. 13A-13B. The cap layer 278 covers the air spacers 276. The cap layer 278 may function as an etch stop layer for the subsequent interconnect layers. In some embodiments, the cap layer 278 has a thickness in a range between about 2 nm to about 50 nm along the z-direction. In some embodiments, the cap layer 278 includes silicon and nitrogen and/or carbon (for example, SiN, SiCN, SiCON, SiON, SiC, and/or SiCO). In some embodiments, the cap layer 278 includes a metal oxide, such as AlOx, AlZrOx, ZrOx, other suitable metal oxide, BN, SiBN, or combinations thereof.

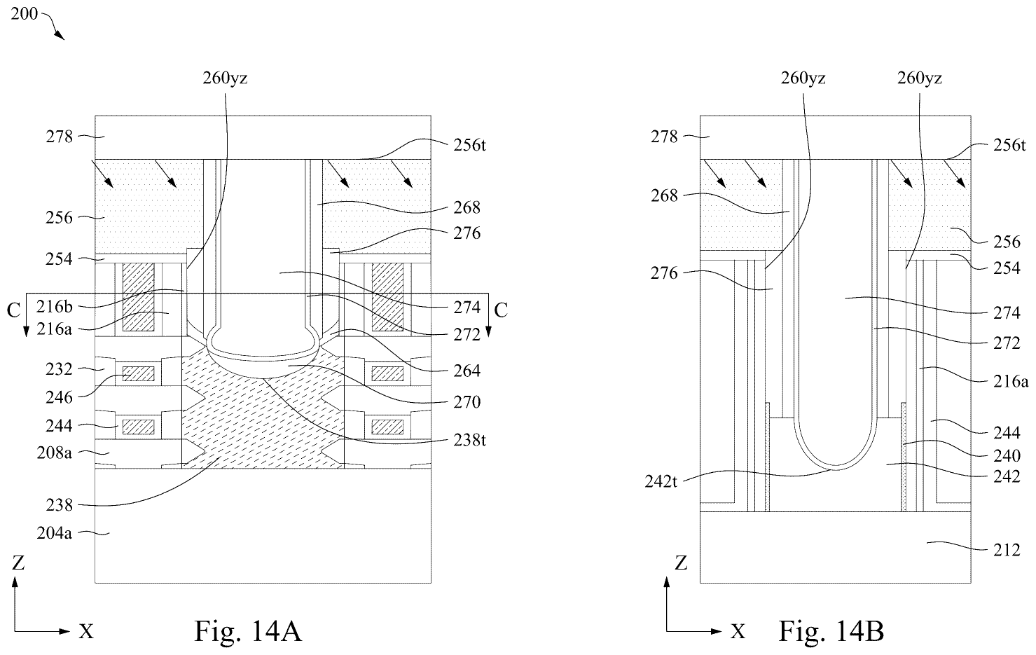

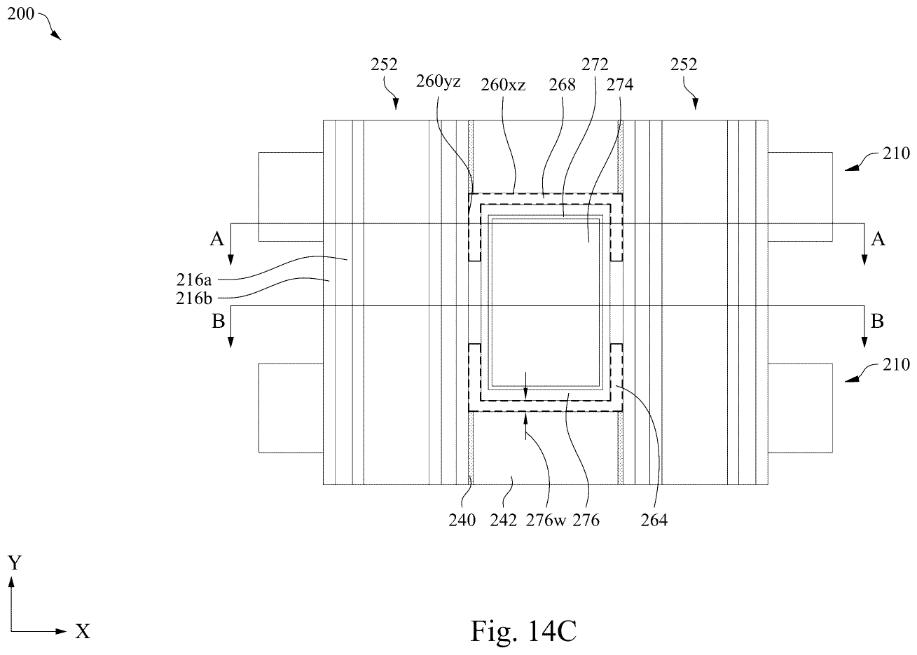

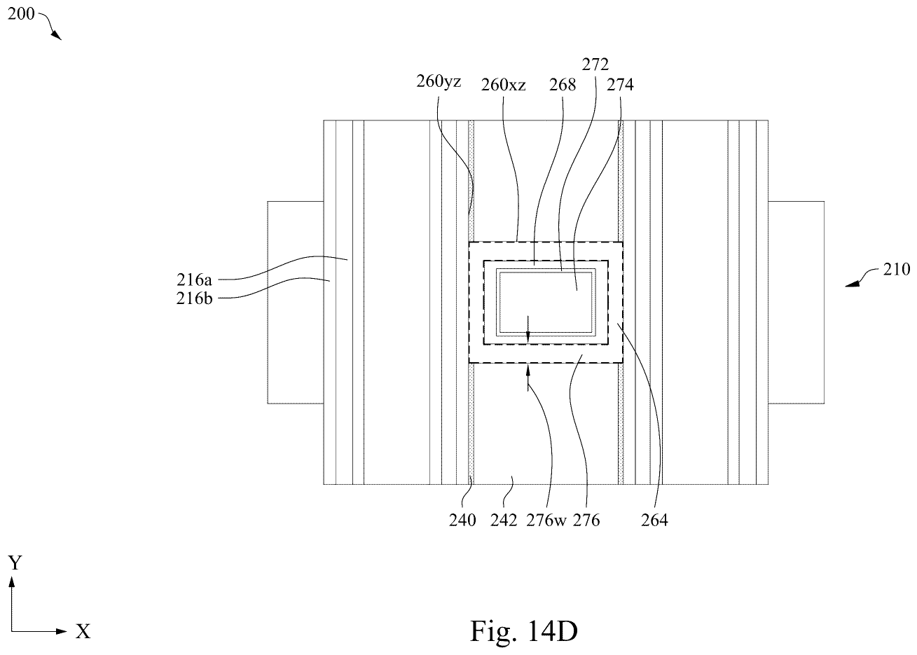

In operation 132, an implantation process is performed to seal the air spacers 276 at upper portions, as shown in FIGS. 14A-14B. In some embodiments, the implantation process is tuned to dope elements into the ILD layer 256, which expands in the x-y plane to seal the air spacers 276. In some embodiments, the dope elements may include germanium (Ge), xenon (Xe), or a combination. In some embodiments, ions of the dope elements may be bombarded towards the ILD layer 256 at an angle. For example, the angle may be in a range between about 45 degrees to about 80 degrees.

After the implantation process, the ILD layer 256 expands beyond the sidewalls 260yz and 260xz of the source/drain contact opening 260 to close off the upper portion of the air spacers 276. In some embodiments, the doped ILD layer 256 is in contact with the contact isolation layer 268.

As shown in FIG. 14A, the air spacer 276 over the source/drain regions 238, 236 is defined between the outer layer 216b of the gate sidewall spacer layer 216 and the contact isolation layer 268 in the x-direction, and between the etch stop layer 264 and the doped ILD layer 256 in the z-direction. As shown in FIG. 14B, the air spacer 276 over the isolation layer 212 is defined between the outer layer 216b of the gate sidewall spacer layer 216 and the contact isolation layer 268 in the x-direction, and between the ILD layer 242 and the doped ILD layer 256 in the z-direction. In some embodiments, the air spacer 276 has a depth along the z-direction. The depth of the air spacer 276 is greater above the isolation layer 212 than above the source/drain region 236/238.

FIG. 14C is a cross section of the semiconductor device 200 along the C-C line in FIG. 14A. As shown in FIG. 14C, the air spacer 276 surrounds the source/drain contact feature 274. Lines A-A and B-B in FIG. 14C provide cross-section lines of FIGS. 14A and 14B. As shown in FIG. 14C, the air spacer 276 includes a continuous gap around the source/drain contact feature 274 in the x-y plane. In some embodiments, the air spacer 276 may have a substantially uniform width 276w around the source/drain contact feature 274. In some embodiments, the width 276w is in a range between about 0.5 nm and about 5 nm.

The source/drain contact feature 274 in FIGS. 14A-14C bridges two unmerged source/drain regions, therefore, including a portion in contact with the ILD layer 242 or the isolation layer 212 in between. As a result, segmented strips of etch stop layers 264 remain at the bottom surface of the air spacer 276. As shown in FIG. 14C, the etch stop layer 264 are two segmented strips disposed at the bottom of the air spacer 276 over the source/drain regions 236, 238 on each side. In FIG. 14C, locations of the etch stop layer 264 are marked by dashed lines. That is to say that the etch stop layer 264 remains at areas between the bottom of the air spacer 276 and the source/drain regions 238. In other words, the etch stop layer 264 separates the source/drain regions 238 and the air spacer 276. In some embodiments, the source/drain contact feature 274 may bridge multiple unmerged source/drain features, resulting in multiple strips of the edge stop layers 264 remain at the bottom surface of the air spacer 276 on each side.

In other embodiments, the source/drain contact feature 274 may be disposed over a single source/drain feature or two or more merged source/drain features, resulting in one continuous strip of the etch stop layer 264 on each side of the air spacer 276, as shown in FIG. 14D. In other words, the etch stop layer 264 is present on the bottom of the air spacer 276 and around the source/drain contact feature 274.

Because air has a dielectric constant that is about one (k≈1), which is lower than dielectric constants of insulating materials conventionally implemented in MLI feature 258 (i.e. from the ILD layers 242, 256 and CESLs 240, 254, marked in FIG. 7A), for example, silicon oxide or silicon nitride, the air spacer 276 reduces a parasitic capacitance between gate structure 252 and the source/drain contact feature 274. As a result, parasitic capacitance and associated RC delay of the semiconductor device 200 is greatly reduced by surrounding the source/drain contact feature 274 with the air spacer 276. Additionally, the air spacer 276 physically separates the source/drain contact features 274 from the ILD layers 242, 256 and CESLs 240, 254, such that metal elements in the source/drain contact features metal diffusion from the source/drain contact feature 274 into the from the ILD layers 242, 256 and CESLs 240, 254. The etch stop layer 264 protects the source/drain regions during formation of the air spacer 276, and facilitates fully removal of the dummy spacer layers and realizes potential volume of the air spacer 276. The present disclosure thus proposes air gap sealing techniques below that preserve integrity of the air spacers 276, so that the semiconductor device 200 can maintain a reduced capacitance and/or resistance characteristics provided by the air spacer 276.

As discussed in the operation 118, the etch stop layer 264 may be formed by depositing a suitable film in place of the plasma treatment process.

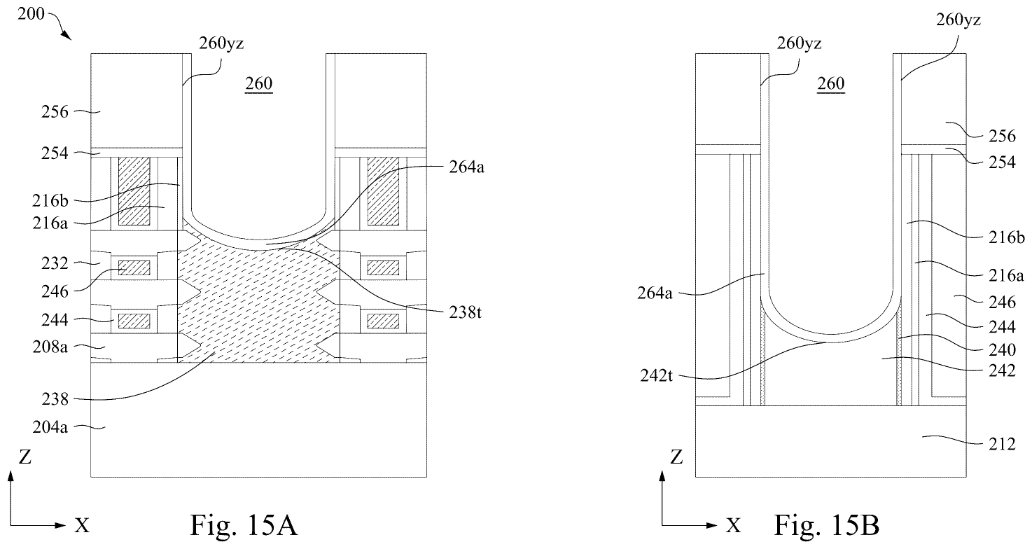

FIGS. 15A-15B, 16A-16B, 17A-17B, and 18A-18C schematically illustrate various stages of manufacturing a semiconductor device 200a according to embodiments of the present disclosure. The semiconductor device 200a is similar to the semiconductor device 200 except that the semiconductor device 200a includes an etch stop layer 264a deposited on the source/drain regions 236, 238. The semiconductor device 200a may be fabricated according to the method 100.

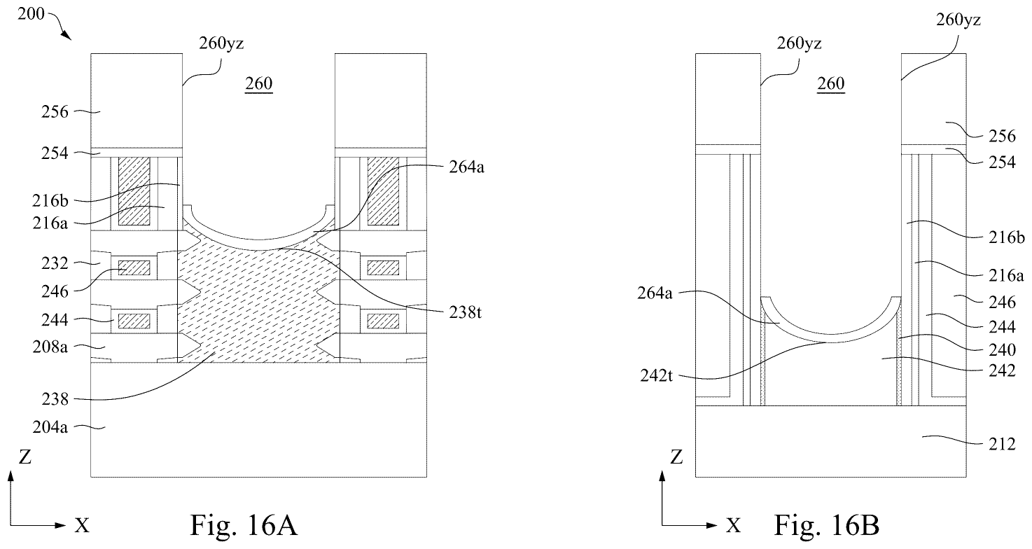

FIGS. 15A-15B and FIGS. 16A-16B schematically illustrate the semiconductor device 200a after operation 118. The etch stop layer 264a may first deposited over all exposed surfaces on the source/drain contact opening 260, including the top surface 238t/236t of the source/drain regions 238/236, the sidewalls 260yz, 260xz, and the top surface 242t of the ILD layer 242 over the isolation layer 212, as shown in FIG. 15A-15B. An anisotropic etch process may then be performed to remove the etch stop layer 264a from the vertically oriented sidewalls 260yz, 260xz, as shown in FIGS. 16A-16B. The etch stop layer 264a remains on the top surface 242t of the ILD layer 242 over the isolation layer 212. Removing the vertical portion may maximize the volume of the air spacers to be formed.

The etch stop layer 264a may include an oxide, a nitride, or a combination. For example, the etch stop layer 264a may include a silicon oxide layer, or a silicon nitride layer. The etch stop layer 264a may be deposited with any suitable methods.

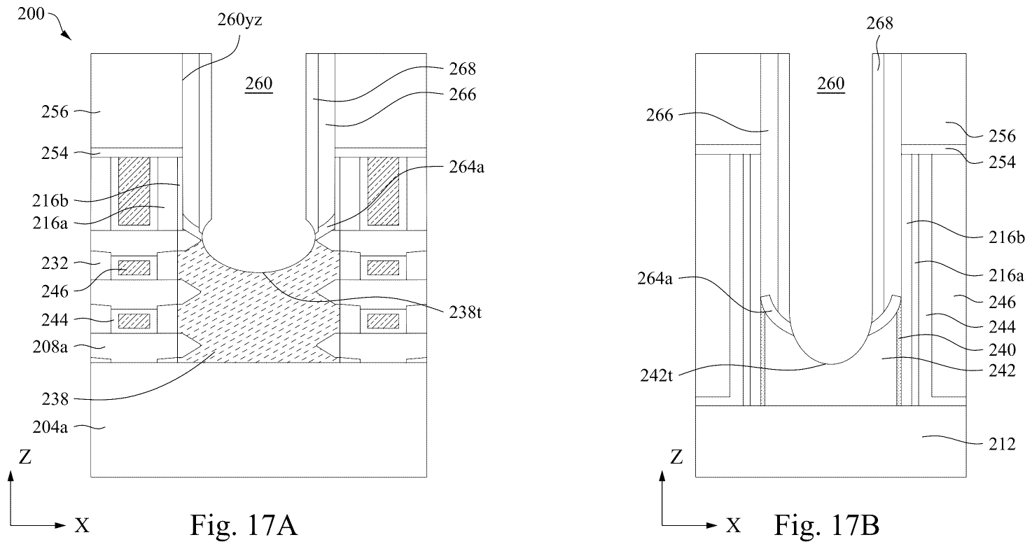

FIGS. 17A-17B schematically illustrate the semiconductor device 200a after operation 124. The dummy spacer layer 266 and the contact isolation layer 268 are sequentially formed on the sidewalls 260yz, 260xz of the source/drain contact opening 260. After operation 124, strips of the etch stop layer 264 remain between the dummy spacer layer 266 and the source/drain regions 238, 236 (FIG. 17A) and between the dummy spacer layer 266 and the ILD layer 242 over the isolation layer 212 (FIG. 17B).

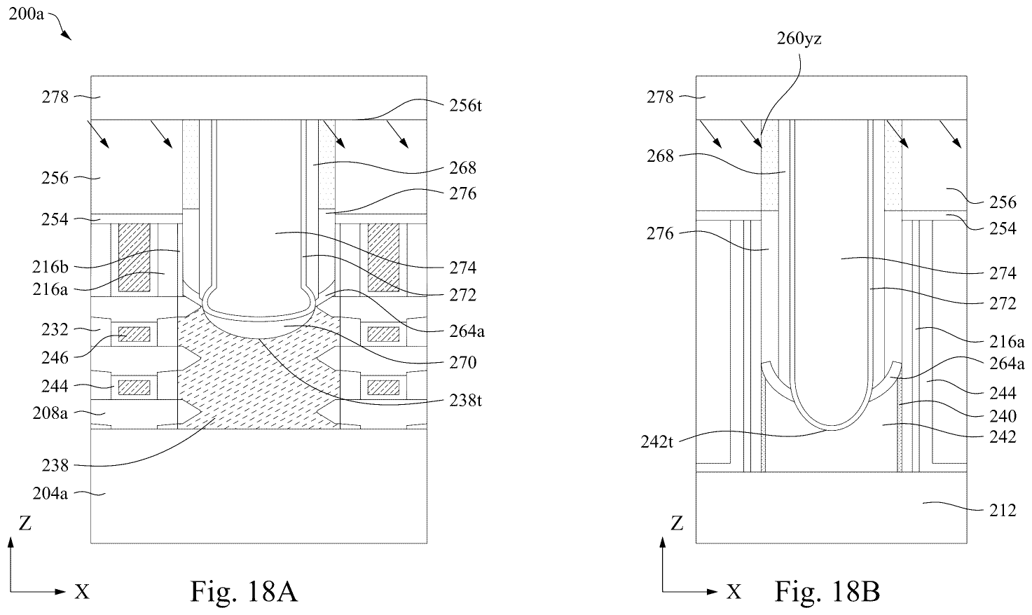

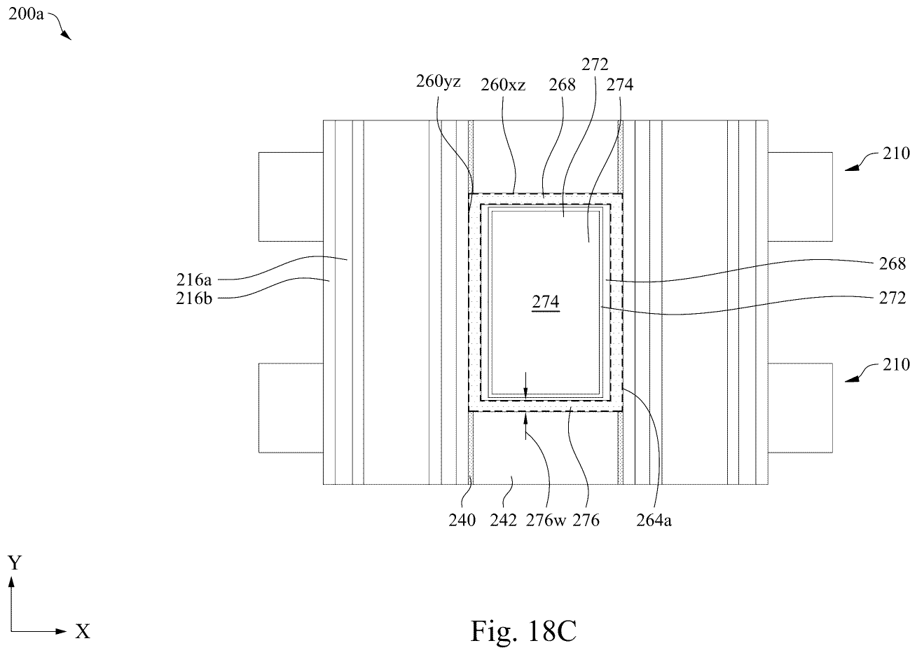

FIGS. 18A, 18B, and 18C schematically illustrate the semiconductor device 200a after operation 132. The air spacer 276 is formed around the source/drain contact feature 274. The air spacer 276 includes a continuous gap around the source/drain contact feature 274 in the x-y plane. The etch stop layer 264a remains in one continuous around the source/drain contact feature 274 on the bottom of the air spacer 276.

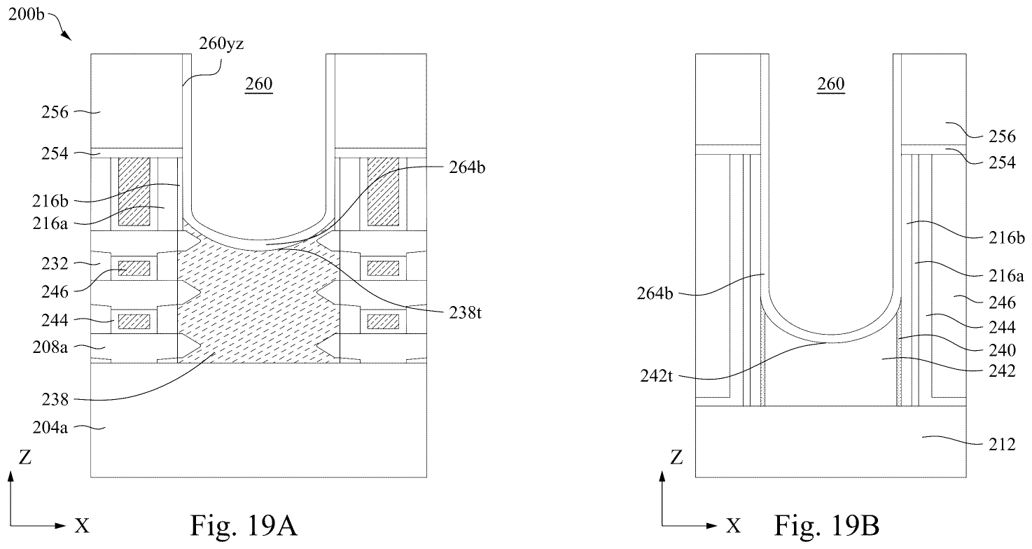

FIGS. 19A-19B, 20A-20B, 21A, 21B, 21C, 21D, and 21E schematically illustrate various stages of manufacturing a semiconductor device 200b according to embodiments of the present disclosure. The semiconductor device 200b is similar to the semiconductor device 200a except that in the semiconductor device 200b, an etch stop layer 264b remains on vertical sidewalls of the source/drain contact opening 260. The semiconductor device 200b may be fabricated according to the method 100.

FIG. 19A-19B schematically illustrate the semiconductor device 200b after operation 118. The etch stop layer 264a may first deposited over all exposed surfaces on the source/drain contact opening 260, including the top surface 238t/236t of the source/drain regions 238/236, the sidewalls 260yz, 260xz, and the top surface 242t of the ILD layer 242 over the isolation layer 212, as shown in FIG. 19A-19B.

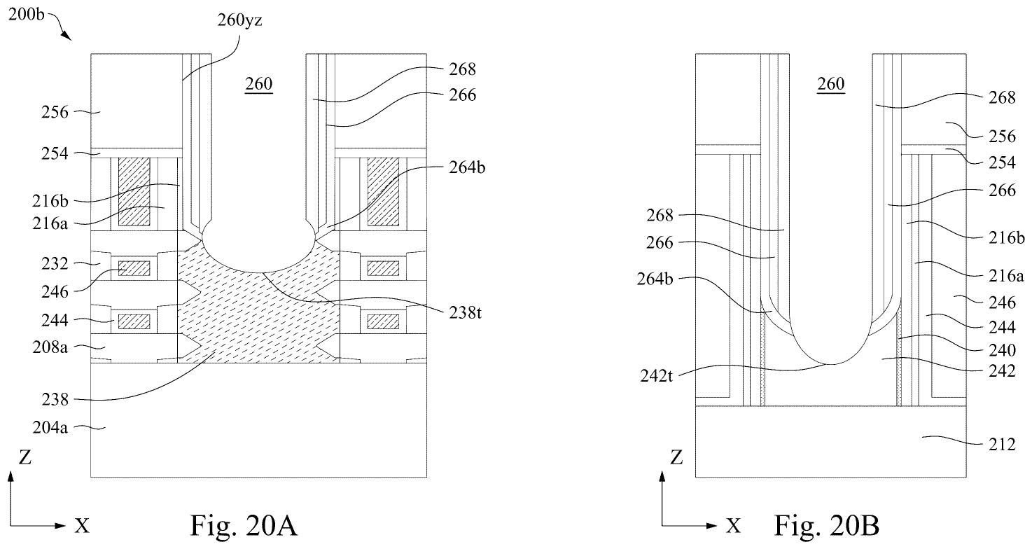

FIGS. 20A-20B schematically illustrate the semiconductor device 200b after operation 124. The dummy spacer layer 266 and the contact isolation layer 268 are sequentially formed on the etch stop layer 264b, which remains on the sidewalls 260yz, 260xz of the source/drain contact opening 260. After operation 124, the dummy spacer layer 266 is sandwiched between the etch stop layer 264b and the contact isolation layer 268.

FIGS. 20A, 20B, and 20C schematically illustrate the semiconductor device 200b after operation 132. The air spacer 276 is formed around the source/drain contact feature 274. The air spacer 276 includes a continuous gap around the source/drain contact feature 274 in the x-y plane. The air spacer 276 is defined between the edge stop layer 264b and the contact isolation layer 268. The etch stop layer 264b remains in one continuous strip extending along the y-direction on the bottom of the air spacer 276 on each side.

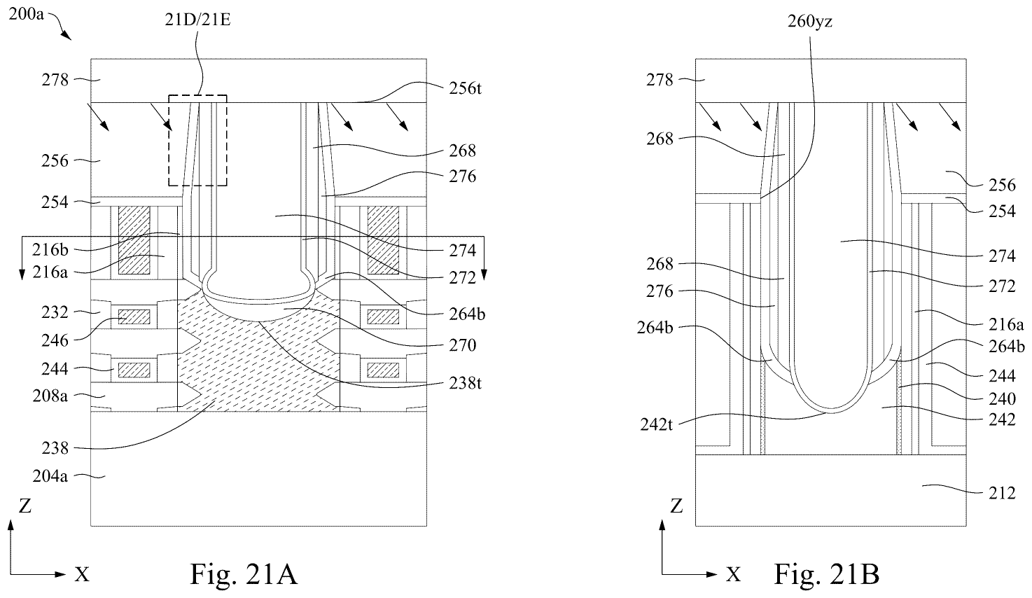

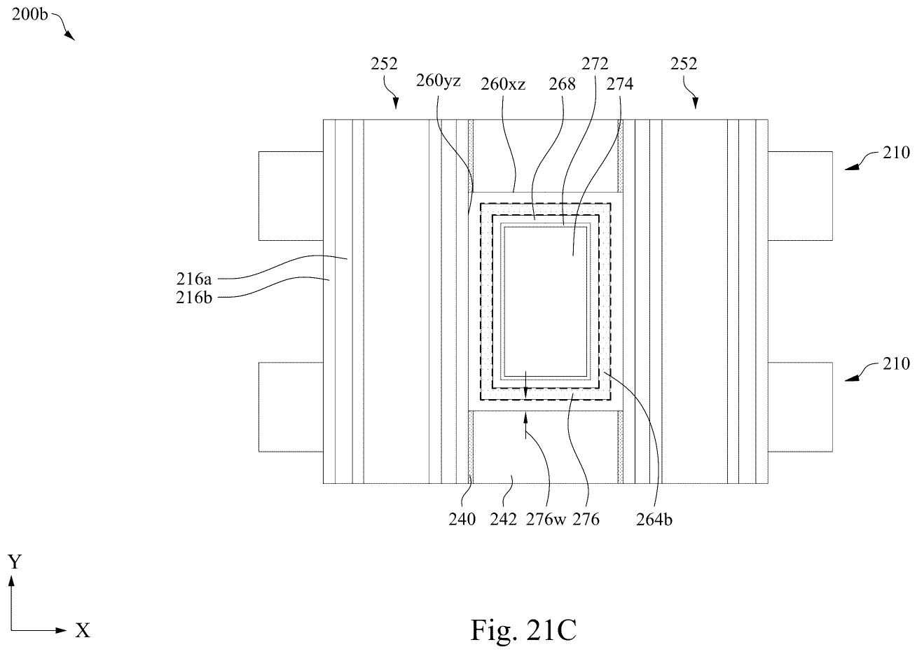

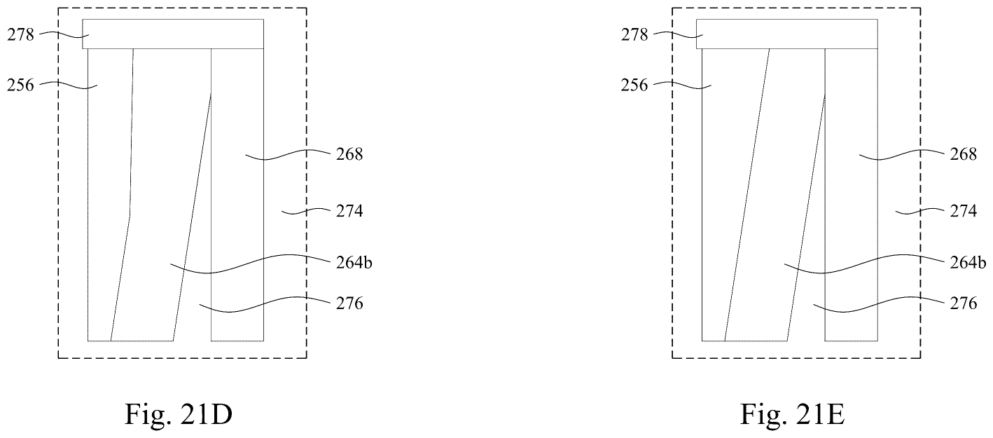

Because the edge stop layer 264b remain on the ILD layer 256 on the sidewalls 260yz, 260xz, an upper portion of the edge stop layer 264b would be pushed towards the contact isolation layer 268 to seal the air spacer 276 during the implantation process in operation 132. In some embodiments, the edge stop layer 264b is pushed to be in contact with the contact isolation layer 268 near the top surface 256t of the ILD layer 256. In some embodiments, the edge stop layer 264 may be tilted along the z-direction, resulting in a gradually narrowing air spacer 276 as shown in FIGS. 21A,21B, and 21C.

FIGS. 21D and 21E are partially enlarged cross-sectional view of the semiconductor device 200b in an area marked 21D/21E in FIG. 21A. As shown in FIGS. 21D and 21E, the air spacer 276 gradually narrows from the ESL layer 254 towards the cap layer 278.

Depending on the composition of the etch stop layer 264b, an upper portion of the etch stop layer 264b may expand during the implantation process. For example, as shown in FIG. 21D, when the etch stop layer 264b includes an oxide material, such as silicon oxide, the etch stop layer 264b thickens from the ESL layer 254 towards the cap layer 278 as a result of the implantation.

As shown in FIG. 21E, when the etch stop layer 264b includes a nitride material, such as silicon nitride, the etch stop layer 264b does not expand as a result of the implantation and remains the same thickness. The expansion of the ILD layer 256 pushes the etch stop layer 264b to tilt.

Various embodiments or examples described herein offer multiple advantages over the state-of-art technology. The air spacer according to the present disclosure reduces parasitic capacitance and associated RC delay in semiconductor devices. By forming a protective etch stop layer between the air spacer and the source/drain regions, embodiments of the present disclosure facilitate substantial removal of the dummy spacer layers and realize potential volume of the air spacers.

Some embodiments of the present provide a semiconductor device, comprising: a gate structure; a source/drain region disposed on a side of the gate structure; a first dielectric layer disposed over the source/drain region; a source/drain contact feature disposed on the source/drain region through the first dielectric layer, wherein an air spacer is formed between the source/drain contact feature and the gate structure; and an etch stop layer disposed between the source/drain region and the air spacer.

Some embodiments of the present disclosure provide a semiconductor device, comprising: a first dielectric layer; a contact etch stop layer formed on the first dielectric layer; a second dielectric layer formed on the contact etch stop layer, wherein the second dielectric layer includes an oxide containing material with a doped element; and a conductive feature disposed in the first dielectric layer, the contact etch stop layer and the second dielectric layer, wherein an air spacer is defined between the conductive feature and the first dielectric layer, and the air spacer is sealed by the second dielectric layer.

Some embodiments of the present disclosure provide a method, comprising: forming a semiconductor structure comprising: a gate structure; a source/drain region on a side of the gate structure; a first dielectric layer disposed on the source/drain region; and a second dielectric layer disposed on the first dielectric layer; forming a contact opening through the second dielectric layer, the first dielectric layer and a portion of the source/drain region, wherein a top surface of the source/drain region is exposed in the contact opening; forming an etch stop layer on the top surface of the source/drain region; forming a dummy spacer layer on sidewalls of the contact opening, wherein the etch stop layer is disposed between the dummy spacer layer and the source/drain region; forming a contact isolation layer on the sidewalls of in the contact opening; removing the etch stop layer from a bottom of the contact opening; forming a source/drain contact feature in the contact opening; and removing the dummy spacer layer from a top surface of the second dielectric layer to form an air spacer around the contact isolation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a gate structure;
a source/drain region disposed on a side of the gate structure;
a first dielectric layer disposed over the source/drain region;
a source/drain contact feature disposed on the source/drain region through the first dielectric layer, wherein an air spacer is formed between the source/drain contact feature and the gate structure; and
an etch stop layer disposed between the source/drain region and the air spacer.

2. The semiconductor device of claim 1, further comprising:
a gate sidewall spacer disposed between the gate structure and the first dielectric layer; and
a contact isolation layer disposed around the source/drain contact feature, wherein the air spacer is defined between the gate sidewall spacer and the contact isolation layer.

3. The semiconductor device of claim 2, further comprising:
a second dielectric layer disposed above the gate structure and the first dielectric layer, wherein the contact isolation layer and the source/drain contact feature are disposed in an opening through the first dielectric layer and the second dielectric layer, and the air spacer is sealed near a top surface of the second dielectric layer.

4. The semiconductor device of claim 3, wherein the second dielectric layer is disposed against the contact isolation layer to seal the air spacer.

5. The semiconductor device of claim 3, wherein the etch stop layer is further disposed on the gate sidewall spacer, and the air spacer is defined between the etch stop layer and the contact isolation layer.

6. The semiconductor device of claim 5, wherein the etch stop layer is further disposed between the second dielectric layer and the contact isolation layer, and the etch stop layer is tilted relative to the contact isolation layer.

7. The semiconductor device of claim 6, wherein the etch stop layer a thickness of the etch stop layer increases towards the top surface of the second dielectric layer.

8. The semiconductor device of claim 3, wherein the second dielectric layer includes an oxide material doped with Ge or Xe.

9. The semiconductor device of claim 2, wherein the air spacer surrounds the source/drain contact feature.

10. The semiconductor device of claim 1, wherein the etch stop layer comprises an oxide material or a nitride material.

11. The semiconductor device of claim 10, wherein the etch stop layer is formed from treating the source/drain region with an oxygen or nitrogen containing plasma.

12. A semiconductor device, comprising:
a first dielectric layer;
a contact etch stop layer formed on the first dielectric layer;
a second dielectric layer formed on the contact etch stop layer, wherein the second dielectric layer includes an oxide containing material with a doped element; and
a conductive feature disposed in the first dielectric layer, the contact etch stop layer and the second dielectric layer, wherein an air spacer is defined between the conductive feature and the first dielectric layer, and the air spacer is sealed by the second dielectric layer.

13. The semiconductor device of claim 12, further comprising:
a source/drain region disposed in the first dielectric layer, wherein the conductive feature is disposed on the source/drain region and in electrical connection with the source/drain region.

14. The semiconductor device of claim 13, further comprising:
an etch stop layer disposed between the air spacer and the source/drain region.

15. A method, comprising:
forming a semiconductor structure comprising:
a gate structure;
a source/drain region on a side of the gate structure;
a first dielectric layer disposed on the source/drain region; and
a second dielectric layer disposed on the first dielectric layer;
forming a contact opening through the second dielectric layer, the first dielectric layer and a portion of the source/drain region, wherein a top surface of the source/drain region is exposed in the contact opening;
forming an etch stop layer on the top surface of the source/drain region;
forming a dummy spacer layer on sidewalls of the contact opening, wherein the etch stop layer is disposed between the dummy spacer layer and the source/drain region;
forming a contact isolation layer on the sidewalls of in the contact opening;
removing the etch stop layer from a bottom of the contact opening;
forming a source/drain contact feature in the contact opening; and
removing the dummy spacer layer from a top surface of the second dielectric layer to form an air spacer around the contact isolation layer.

16. The method of claim 15, wherein forming the etch stop layer on the source/drain region comprises:
treating the top surface of the source/drain region with a plasma.

17. The method of claim 16, wherein the plasma containing oxygen or nitrogen.

18. The method of claim 15, wherein forming the etch stop layer on the source/drain region comprises:
depositing an oxide material or a nitride material on the top surface of the source/drain region.

19. The method of claim 15, further comprising:
implanting the second dielectric layer to seal the air spacer between the second dielectric layer and the contact isolation layer.

20. The method of claim 19, wherein implanting the second dielectric layer comprises implanting the second dielectric layer with Ge or Xe.
